(19) United States
(12) Patent Application Publication
(10) Pub. No.: US 2025/0194053 A1
(43) Pub. Date: Jun. 12, 2025

(54) HEAT SINK ASSEMBLIES HAVING ELLIPTICAL FINS AND BAFFLE AND AIRCRAFT INCLUDING THE SAME

(71) Applicant: Toyota Motor Engineering & Manufacturing North America, Inc., Plano, TX (US)

(72) Inventors: Tianzhu Fan, Houston, TX (US); Feng Zhou, Ann Arbor, MI (US); Ercan M. Dede, Ann Arbor, MI (US); Tom M. Neuman, Fairfax, VA (US)

(73) Assignees: Toyota Motor Engineering & Manufacturing North America, Inc., Plano, TX (US); Toyota Jidosha Kabushiki Kaisha, Aichi-ken (JP)

(21) Appl. No.: 18/941,794

(22) Filed: Nov. 8, 2024

Related U.S. Application Data
(60) Provisional application No. 63/608,966, filed on Dec. 12, 2023.

(51) Int. Cl. H05K 7/20; B64C 3/38; B64D 47/00

(52) U.S. Cl. CPC H05K 7/2039; B64C 3/38; B64D 47/00; H05K 7/209

(57) ABSTRACT

In one embodiment, a heat sink assembly includes a heat sink including a plate having a surface. The heat sink assembly also includes an array of fins extending from the surface, where each fin is elliptical in cross section such that each fin has a length that is greater than a width, and fins of the array of fins are aligned such that an axis defined by the length is in a common direction among the array of fins. The heat sinks may be provided on a baffle that can transition between a retracted state and an inclined state.

### CROSS-REFERENCE TO RELATED APPLICATIONS

This application claims priority to U.S. Provisional Application No. 63/608,966 filed on Dec. 12, 2023, which is hereby incorporated in its entirety.

### BACKGROUND

Over the past decade, thermal management technologies for power electronics in traditional carriers, such as electric vehicles and large-scale energy storage systems, have seen significant advancements. Primarily, air cooling and liquid cooling have emerged as the dominant cooling methodologies. Air cooling, celebrated for its simplicity and reliability, typically offers a convective coefficient of less than 1000 W/m²·K. In contrast, liquid cooling methods, which include cold plate cooling, micro-channel cooling, and immersion cooling, can achieve a much higher convective coefficient but are often encumbered by intricate and sizable loop systems. Furthermore, the advent of wide bandgap (WBG) semiconductors, such as GaN and SiC, introduces demands for greater power, increased switching frequencies, and elevated voltages. To address the resulting extreme hot spots, phase-change cooling presents as a next-generation solution. Notably, vapor chambers utilizing water evaporation within microporous structures can attain an impressive equivalent thermal conductivity exceeding 10000 W/m²·K, efficiently redistributing heat from hot spots.

Unmanned Aerial Vehicles (UAVs) powered by electricity, termed Electrical Unmanned Aerial Vehicles (E-UAVs), are rapidly gaining traction in civil applications. However, while both liquid cooling and phase-change cooling are proven effective for high-power-density electronics, their application to the aircraft applications, such as E-UAV is challenging. The inherent weight, volume restrictions, and operational conditions like high altitudes and unstable environments of E-UAVs make these cooling solutions less feasible.

Accordingly, alternative systems and methods for a ir-cooling high-power density electronics in aircraft applications may be desired.

### BRIEF SUMMARY

In one embodiment, a heat sink assembly includes a heat sink including a plate having a surface. The heat sink assembly also includes an array of fins extending from the surface, where each fin is elliptical in cross section such that each fin has a length that is greater than a width, and fins of the array of fins are aligned such that an axis defined by the length is in a common direction among the array of fins.

In another embodiment, an assembly includes a power electronics package having a plurality of power electronic devices. The assembly also includes a heat sink thermally coupled to the power electronics package. The heat sink includes a plate having a surface and an array of fins extending from the surface. Each fin is elliptical in cross section such that each fin has a length that is greater than a width, and the fins of the array of fins are aligned such that an axis defined by the length is in a common direction among the array of fins.

In another embodiment, an aircraft includes an airfoil having a recess and a power electronics package that includes a plurality of power electronic devices. The aircraft also includes a heat sink thermally coupled to the power electronics package. The heat sink includes a plate having a surface and an array of fins extending from the surface, where each fin is elliptical in cross section such that each fin has a length that is greater than a width, and fins of the array of fins are aligned such that an axis defined by the length is in a common direction among the array of fins. The heat sink also includes an actuator coupled to the plate and operable to move the plate between a retracted position and an inclined position, where when the plate is in the retracted position the plate is within the recess of the airfoil.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates an example aircraft according to one or more embodiments described and illustrated herein.

FIG. 2 illustrates an example electronics package according to one or more embodiments described and illustrated herein.

FIG. 3 illustrates an example heat sink according to one or more embodiments described and illustrated herein.

FIG. 4 illustrates another example heat sink according to one or more embodiments described and illustrated herein.

FIG. 5 illustrates another example heat sink according to one or more embodiments described and illustrated herein.

FIG. 6A illustrates a top view of the example heat sink of FIG. 5 according to one or more embodiments described and illustrated herein.

FIG. 6B illustrates a top view of another example heat sink according to one or more embodiments described and illustrated herein.

FIG. 6C illustrates a top view of another example according to one or more embodiments described and illustrated herein.

FIG. 6D illustrates a top view of another according to one or more embodiments described and illustrated herein.

FIG. 7A illustrates a perspective view of an individual fin of a heat sink according to one or more embodiments described and illustrated herein.

FIG. 7B illustrates a plot of function temperature versus fin height according to one or more embodiments described and illustrated herein.

FIG. 7C illustrates a plot of drag force versus fin height according to one or more embodiments described and illustrated herein.

FIG. 7D illustrates a plot of drag force versus airflow velocity for four heat sink designs according to one or more embodiments described and illustrated herein.

FIG. 7E illustrates a plot of junction temperature versus airflow velocity for four heat sink designs according to one or more embodiments described and illustrated herein.

FIG. 7F illustrates a plot of thermal resistance versus aircraft velocity for four heat sink designs according to one or more embodiments described and illustrated herein.

FIG. 8 illustrates an example airfoil having a baffle and a heat sink according to one or more embodiments described and illustrated herein.

FIG. 9A illustrates a plot of drag force versus incline angle of a baffle for a heat sink design according to one or more embodiments described and illustrated herein.

FIG. 9B illustrates a plot of junction temperature versus incline angle of a baffle for a heat sink design according to one or more embodiments described and illustrated herein.

FIG. 9C illustrates a plot of drag as a function of airflow velocity according to one or more embodiments described and illustrated herein.

FIG. 9D illustrates a plot of junction temperature as a function of airflow velocity according to one or more embodiments described and illustrated herein.

FIG. 10 illustrates an example airfoil having a plurality of electronic assemblies and a plurality of baffles according to one or more embodiments described and illustrated herein.

FIG. 11A illustrates a stack of covers that fully cover a plurality of heat sinks according to one or more embodiments described and illustrated herein.

FIG. 11B illustrates a stackable cover for fully covering a heat sink according to one or more embodiments described and illustrated herein.

FIG. 12A illustrates a stack of covers that partially cover a plurality of heat sinks according to one or more embodiments described and illustrated herein.

FIG. 12B illustrates a cover that partially covers a heat sink according to one or more embodiments described and illustrated herein.

FIG. 13 illustrates an actuatable plate having a heat sink in a retracted state according to one or more embodiments described and illustrated herein.

FIG. 14 illustrates the actuatable plate having a heat sink of FIG. 13 in an inclined state according to one or more embodiments described and illustrated herein.

### DETAILED DESCRIPTION

Embodiments of the present disclosure leverage the uncomplicated nature of direct air cooling for aircraft applications, which is attractive for E-UAVs. The swift operational speeds of E-UAVs naturally ensure abundant airflow over their surfaces, offering a potential avenue for heat dissipation from power electronic converters.

These applications span a diverse range, from medical services and agriculture to disaster relief and geological surveys. When compared to traditional aerial vehicles, E-UAVs excel due to their precision, resilience, efficiency, and reliability. The contemporary E-UAV encompasses a myriad of components: sensory (such as cameras, radars, and lidar), task-specific physical units, communication modules (including cellular, Bluetooth, and WiFi capabilities), energy and power systems, among others. As the demand for enhanced functionalities, longer operation times, and increased endurance grows, the power requirements of E-UAVs are expected to escalate. Central to the power system of E-UAVs is the energy storage, often relying on Li-ion batteries, paired with power electronics and control mechanisms, and propellers. The power electronic inverter, which facilitates the transfer of direct current electrical energy from the battery to alternating current electrical power to the propeller, driving the UAV. However, as the power demands of modern E-UAVs surge, these inverters have emerged as primary heat sources, attributable to the inherent switching and copper losses during operation. As a result, an effective thermal management system for the power electronic converter is a consideration for the E-UAV.

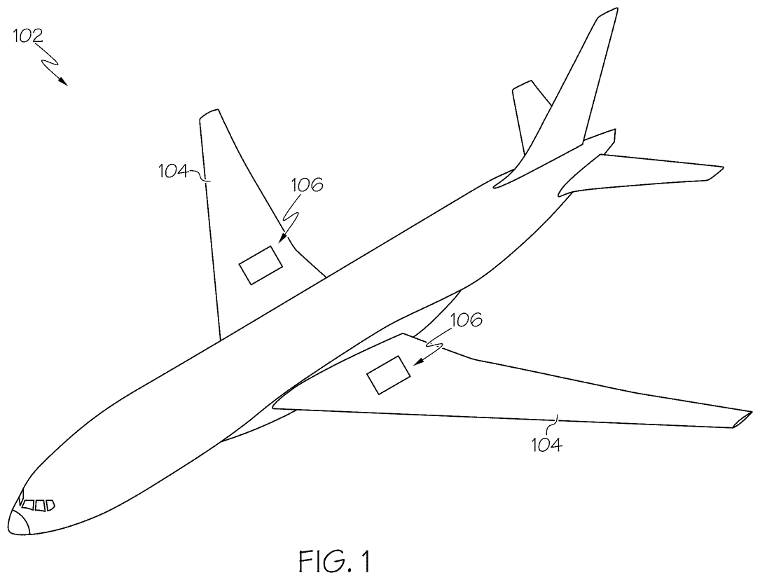

The feasibility of using direct air cooling for dissipating heat from a MOSFET transistor array in E-UAVs, leveraging an externally exposed heat sink on the UAV's airfoil, was evaluated. FIG. 1 illustrates an example aircraft 102, such as a E-UAV, having electronics assemblies 106 with exposed heat sinks, as described in more detail below. In aerodynamic heat sinks it is desirable to have low drag force and pressure drop to avoid elevating the overall energy costs associated with flight drag. Therefore, the heat sinks described herein strike a balance between efficient heat dissipation and minimal drag, using the numerical simulation as the primary tool. The fin shape, configuration, and height are provided in an optimal heat sink design. More particularly, the heat sinks of the present disclosure comprise elliptical fins with a graded fin density exposed to airflow. A major design challenge is the dual objective of maintaining low thermal resistance during slower flight and limiting drag during faster flight-goals that are typically in conflict. To address this, in some embodiments a prepositioned movable front baffle is provided, with the front baffle's optimal inclination identified at approximately 15 degrees. However, the moveable panel may be inclined at any other suitable angle.

The parameters and values that were utilized in optimization and design of the heat sinks of the present disclosure are shown in Table 1 below. It should be understood that there were two typical modes for the E-UAV, the climbing mode, and the full speed mode. The evaluated air speeds through the heat sink were 70 mph and 188 mph, respectively. However, the system may operate at any other suitable air speed. The Reynolds number (Re) of the flow field can be estimated as follows,

$$R e = \frac{ρ \cdot u \cdot L}{μ} \qquad Eq . ( 1 )$$

where u was the flow speed, p was the fluid density, μ was the dynamic viscosity, and L was the characteristic length. The Reynolds number falls into 10³˜10⁴ in this case if using the gap between fins as the characteristic length, which indicated the transition regions between the laminar flow and turbulent flow for the external flow through an airfoil. To simplify the study and save the computational power for multi-physics simulation, the laminar flow condition was chosen in this study. It should be noticed that this was an appropriate under-estimation method in engineering. The designed heat sinks were expected to have better thermal performance if the turbulence flow happened, as it usually indicated enhanced flow mixing and higher Nusselt numbers.

TABLE 1
The parameters and values utilized

| Parameters | Values | | Parameters | Values | |
|---|---|---|---|---|---|
| Total power loss | 82 | W | Inlet air speed | 70 mph at | |
| | | | | Climbing mode; | |
| | | | | 188 mph at full | |
| | | | | speed mode | |
| Inlet air | 46 | Celsius | Inlet air density | 1 | kg/m³ |
| temperature | | | (sea level) | | |
| Heat sink | 53 cm × 89 cm × | | Heat sink material | aluminum | |
| base size | 3.0 mm (W × L × H) | | | | |
| Size of MOSFET | 7 mm × 9 mm × 1 | | Numbers of MOSFET | 25 | |
| transistor | mm (W × L × H) | | transistors | | |
| MOSFET transistor | ~5 | W/cm² | Reynolds Number | 10³~10⁴ | |
| heat flux | | | | | |
| Default thermal | 0.6 | K/W | Junction | ~130 | Celsius |
| resistance from | | | temperature limit | | |
| the to the | | | | | |
| junction | | | | | |

The junction temperature of power electronic device, which may be a metal-oxide-semiconductor field-effect transistor (MOSFET), should be lower than 130 Celsius to ensure it functions normally. The default thermal resistance Rₜₕ from the heat sink base to the transistor junction was 0.55 K/W. Therefore, the junction temperature T_{junc} can be estimated as follows,

$${T}_{junc} = {T}_{base} + R \text{?} \cdot Q \qquad Eq . ( 2 )$$

$$\text{?} \text{indicates text missing or illegible when filed}$$

where T_{base} was the temperature of heat sink base and Q was the power loss from the power electronic converter. The thermal resistance of heat sinks R_{HS} was another parameter and calculated as follows:

$$R \text{?} = \frac{{T}_{base} - {T}_{inlet}}{Q} \qquad Eq . ( 3 )$$

$$\text{?} \text{indicates text missing or illegible when filed}$$

COMSOL Multiphysics® was applied as the tool for the numerical simulation, and several modules were utilized including heat transfer in solids and fluids, Laminar flow, and non-isothermal flow. The number of meshes in the study was around 1×10⁷. The grid independent study was implemented to ensured that the results were not significantly affected by the mesh quality. The continuity equation and Naiver-Stokes equation for a laminar and compressible flow with constant dynamic viscosity were described as follows:

$$\frac{\partial p}{\partial t} + ∇ \cdot ( ρ u ) = 0 \qquad Eq . ( 4 )$$

$$ρ ( \frac{\partial u}{\partial t} + u \cdot ∇ u ) = - ∇ p + μ {∇}^{2} u + \frac{1}{3} μ ∇ ( ∇ \cdot u ) + ρ g ) \qquad Eq . ( 5 )$$

where p is the fluid pressure and ρ is the fluid density. The time dependent terms in the above equations were equal to zero for the steady-state simulation. Also, the heat transfer equations were provided as follows:

$$ρ {C}_{p} u \cdot ∇ T + ∇ \cdot q = Q \qquad Eq . ( 6 )$$

$$q = \text{?} k ∇ T \qquad Eq . ( 7 )$$

$$\text{?} \text{indicates text missing or illegible when filed}$$

The drag force of heat sink structures can be estimated by integrating the fluid pressure at the inlet surface of the flow channel as follows:

$${F}_{d} = \int {pdA}_{inlet} \text{?} \int {pdA}_{ref} \text{?} \qquad Eq . ( 8 )$$

$$\text{?} \text{indicates text missing or illegible when filed}$$

where Aᵢₙₗₑₜ denotes the inlet surface of flow channel with the corresponding heat sink structure, and A_{ref} denotes the inlet surface of an empty flow channel as the reference.

Referring now to FIG. 1, an example aircraft 102 is illustrated. The aircraft 102 may be any type of aircraft, including a plane, a E-UAV, an electric vertical take-off and landing vehicle (eVTOL), a helicopter, and the like. The aircraft 102 includes airfoils 104, which in the illustrated embodiment are configured as wings. Electric motors of the aircraft 102 (not shown) are controlled by inverter circuits provided by one or more electronics assemblies 106 that include power electronic devices that generate alternating current (AC) electrical power from direct current (DC) electrical power provided by one or more batteries of the aircraft 102. The AC electrical power is provided to the electric motors of the aircraft 102 to control the aircraft 102 in the environment. As described in more detail below, the electronics assemblies 106 include exposed heat sinks that cool power electronic devices such that they operate below their maximum operating temperature (e.g., 130 Celsius).

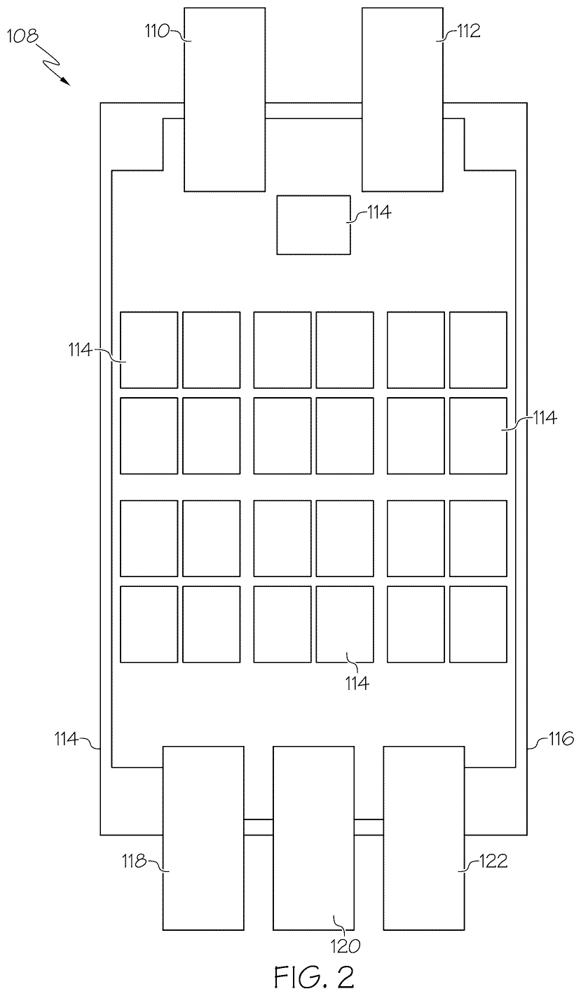

FIG. 2 illustrates an example electronics package 108 that is a component of the electronics assembly 106 shown in FIG. 1. The electronics package 108 generally includes a housing 116 and a plurality of power electronic devices 114, which may be MOSFETs or other semiconductor switching devices, such as power transistors an insulated-gate bi-polar transistors (IGBT). In the illustrated embodiment the electronics package includes twenty-five power electronic devices 114; however, more or fewer power electronic devices 114 may be provided. The electronics package 108 may include additional components that are not shown, such as gate drive electronic devices, resistors, capacitors, integrated circuit chips, and the like. The electronics package 108 includes a first input terminal 110 (e.g., positive DC voltage input) and a second input terminal (e.g., negative DC voltage input) that are operable to be electrically coupled to a voltage terminals of a battery, such as the aircraft 102 battery. The electronics package 108 provides three-phase output provided at a first output terminal 118, a second output terminal 120, and a third output terminal 122, which are operable to be electrically coupled to the windings of an electric motor of the aircraft 102.

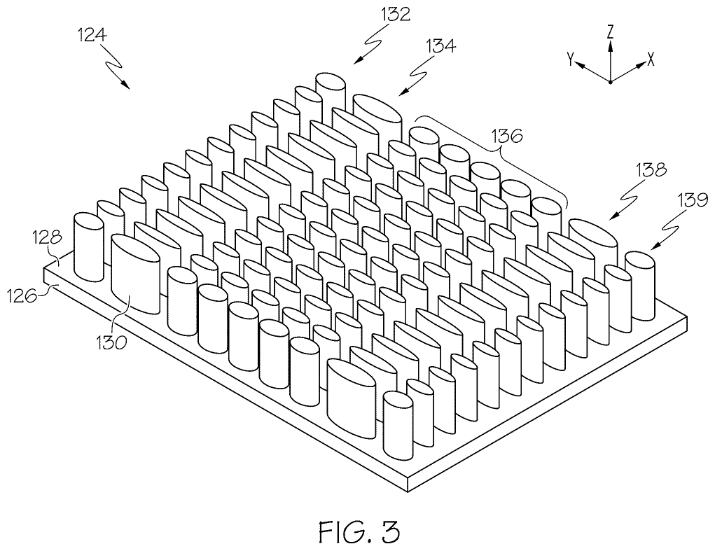

A benchmark configured a rectangular-fin heat sink was used. Each of the rectangular fins had a default height of 10 mm, a thicknesses of the rectangular fins were diverse and followed a distribution of 3.5 mm/2.0 mm/1.4 mm. Initially during the optimization, the fin shape was shifted from the rectangular to elliptical, with remaining same long axis and short axis lengths, as shown in FIG. 3. The heat sink 124 includes a plate 126 having a surface 128 from which an array of fins 130 extends. Gaps between the fins 130 provide space for airflow. The array of fins 130 are arranged in a plurality of groups, which each group having the same length in the y-axis direction. For example, the fins 130 are arranged in a first group of fins 132, a second group of fins 134, a third group of fins 136, a fourth group of fins 138, and a fifth group of fins 139. The third group of fins 136 has several rows of fins 130 while the remaining groups have one row of fins 130. The width of the fins 130 followed the varied distribution from the benchmark, with widths of 3.5 mm/2.0 mm/1.4 mm. The widths of the fins 130 inwardly decrease along the rows for the edges of the array to the center.

As a result of the elliptically shaped fins 130, the drag force of the heat sink 124 was reduced from 1.41 N in the benchmark to 1.11 N in the design of FIG. 3 at the climbing mode, and the maximum junction temperature was decreased from 121.4 Celsius to 115.9 Celsius. Without being bound by theory, this improvement came from the lower pressure drop when the air flew through the elliptical fins 130, resulting a smaller low-speed region at the front of fins and increasing air velocities within the fin gaps, therefore, enhanced the thermal convection coefficient and decreased the junction temperature.

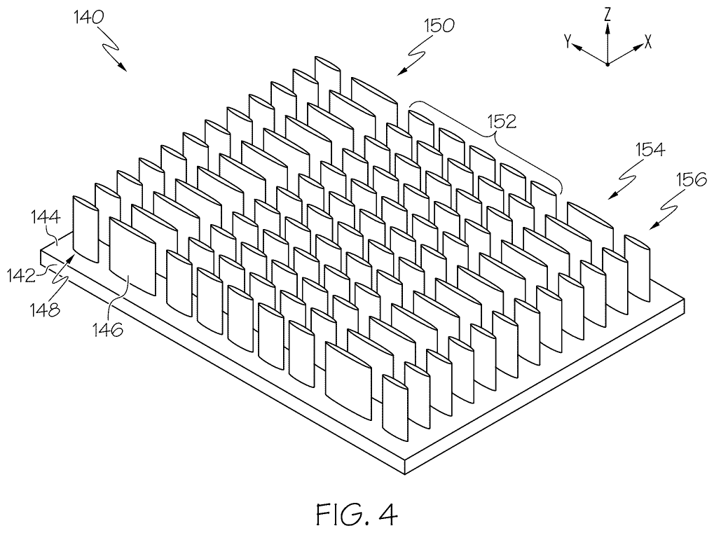

Referring to FIG. 4, the short axis length (i.e., width or thickness) of the elliptical fins along the x-axis was then decreased to a standard 1.0 mm for all fins 146. Like the embodiment of FIG. 3, the heat sink 140 of FIG. 4 has an array of fins 146 extending from a surface 144 of a plate 142 arranged in a first group of fins 148, a second group of fins 150, a third group of fins 152, a fourth group of fins 154, and a fifth group of fins. The third group of fins 152 has several rows of fins 130 while the remaining groups have one row of fins 130. In this embodiment, the drag force was 0.71N and the maximum junction temperature was 112 Celsius. Therefore, reducing and standardizing the width of the fins 146 further reduced both the drag and the maximum junction temperature.

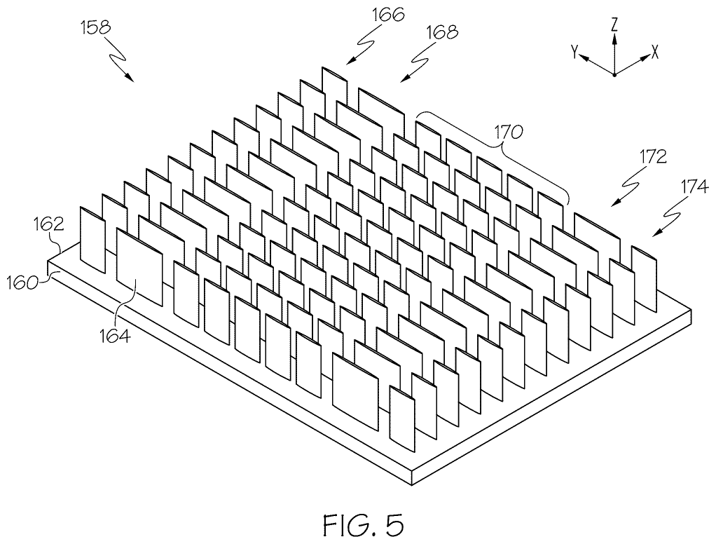

FIG. 5 illustrates an embodiment wherein the short axis length of the elliptical fins along the x-axis was then decreased to a standard 0.6 mm for all fins 164. Like the embodiment of FIG. 4, the heat sink 158 of FIG. 5 has an array of fins 164 extending from a surface 162 of a plate 160 arranged in a first group of fins 166, a second group of fins 168, a third group of fins 170, a fourth group of fins 172, and a fifth group of fins 174. The third group of fins 170 has several rows of fins 164 while the remaining groups have one row of fins 164. In this embodiment, the drag force was 0.64N and the maximum junction temperature was 112.8 Celsius. Therefore, reducing the width of the fins 164 further from 1 mm reduced the drag and only marginally increased the maximum junction temperature.

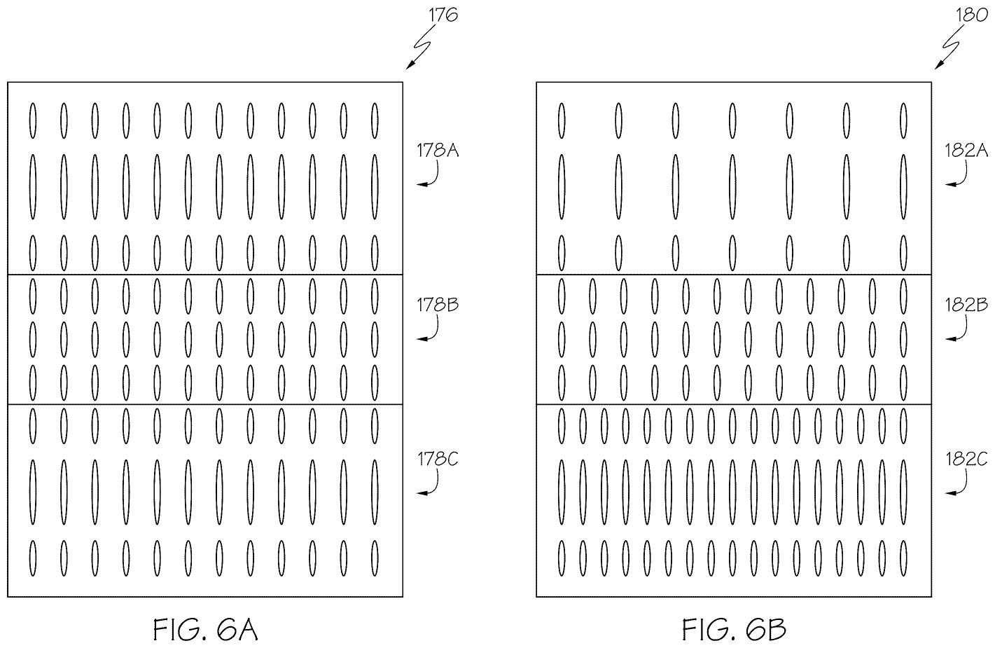

The elliptical fin 164 with a short axial length at 0.6 mm was selected for further optimization. The fin distribution was then changed to investigate its effect on the velocity field, drag force, heat sink base temperature field, and maximum junction temperature. FIG. 6A shows that the array of fins of a heat sink 176 was divided into three groups: a first group of fins 178a, a second group of fins 178b, and a third group of fins 178c as shown in FIG. 6A. In this comparative example, the fin density was equal in all three groups (3×12). This is example is structurally unchanged as compared to FIG. 5.

The fin density was then varied in the groups for performance evaluation. Referring to FIG. 6B, the array of fins of a heat sink 180 was divided into three groups: a first group of fins 182a, a second group of fins 182b, and a third group of fins 182c as shown in FIG. 6B. Each group of fins has a different fin density, which increases from the first group of fins 182a to the third group of fins 182c. In the illustrated example of FIG. 6B, the first fin density of the first group of fins 182a is 3×9 fins, the second fin density of the second group of fins 182b is 3×12 fins, and the third fin density of the third group of fins 186c is 3×15. Thus, the fin density was gradually decreased in the up-wind array and increased in the downside array.

As a result, it was found that when the fin distribution was altered to 3×9/3×12/3×15, when maximum junction temperature was decreased from 112.8 Celsius to 110 Celsius compared to the original configuration at 3×12/3×12/3×12 as shown in FIG. 6A. This may be because the loose fin distribution in the up-wind array decreased the structural drag to the oncoming airflow, and the dense fin distribution in the downside array with increased air velocity enhanced the heat dissipation from the primary transistor hot spots. The drag force was increased to 0.77N as compared to the 0.64N of the example of FIG. 6A.

Referring to FIG. 6C, similar the heat sink 180 of FIG. 6B, to the array of fins of a heat sink 180 was divided into three groups: a first group of fins 186a, a second group of fins 186b, and a third group of fins 186c as shown in FIG. 6C. Each group of fins has a different fin density, which increases from the first group of fins 186a to the third group of fins 186c. In the illustrated example of FIG. 6C, the first fin density of the first group of fins 186a is 3×7 fins, the second fin density of the second group of fins 186b is 3×12 fins, and the third fin density of the third group of fins 182c is 3×17. In this example, the maximum junction temperature was decreased from 110 Celsius to 109.3 Celsius as compared to the example of FIG. 6B. However, the drag force was increased to 0.84N as compared to 0.77N of the example of FIG. 6B.

Referring to FIG. 6D, similar the heat sink 180 of FIG. 6B, to the array of fins of a heat sink 188 was divided into three groups: a first group of fins 190a, a second group of fins 190b, and a third group of fins 190c as shown in FIG. 6D. Each group of fins has a different fin density, which increases from the first group of fins 190a to the third group of fins 190c. In the illustrated example of FIG. 6A, the first fin density of the first group of fins 190a is 3×5 fins, the second fin density of the second group of fins 190b is 3×12 fins, and the third fin density of the third group of fins 190c is 3×19. In this example, the maximum junction temperature was increased from 109.3 Celsius to 110.2 Celsius as compared to the example of FIG. 6C. The drag force was also increased to 0.96N as compared to 0.84N of the example of FIG. 6C.

Thus, it was concluded that further shifting the number of fins in the upwind and downside arrays did not significantly improve the thermal performance, in contrary, increased the overall structural drag force.

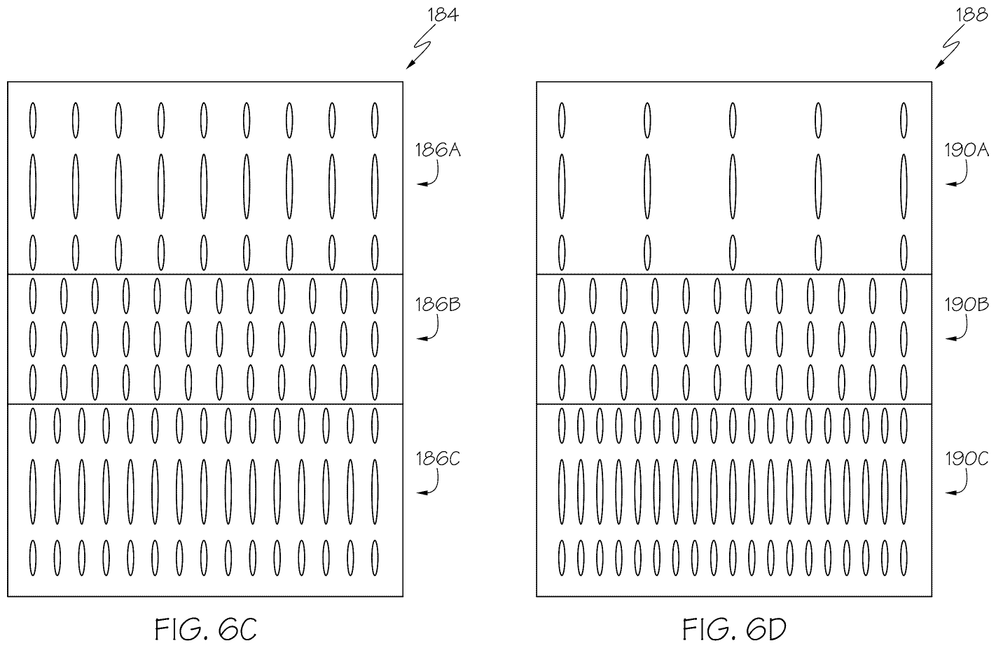

In addition, the effect of fin height on the junction temperature and drag force was also investigated at the climbing mode using the optimized elliptical heat sink 180 with non-uniform fin distribution (FIG. 6B). FIG. 7A shows the height of an example fin 130. FIGS. 7B-7F plot various performance parameters with respect to fin height. Particularly, FIG. 7B plots junction temperature as a function of fin height H. The junction temperature decreases with an increasing fin height in an exponential decay curve. FIG. 7C plots draft force as a function of fin height H. The drag force linearly increases with an increasing fin height.

FIG. 7D plots drag force as a function of aircraft velocity for three fin heights with the configuration of the heat sink 180 of FIG. 6B as well as a comparative example using rectangular fins. A fin height of 3 mm shows the lowest draft force for the highest air velocity.

FIG. 7E plots junction temperature as a function of aircraft velocity for three fin heights with the configuration of the heat sink 180 of FIG. 6B as well as a comparative example using rectangular fins. A fin height of 6 mm shows the lowest draft force for the highest air velocity. It is noted that when the height of the fin decreased to 3 mm, the junction temperature approached the limit at 130 Celsius, corresponding to the minimum fin height in this design.

FIG. 7F plots thermal resistance as a function of aircraft velocity for three fin heights with the configuration of the heat sink 180 of FIG. 6B as well as a comparative example using rectangular fins. A fin height of 6 mm shows the lowest thermal resistance for the highest air velocity.

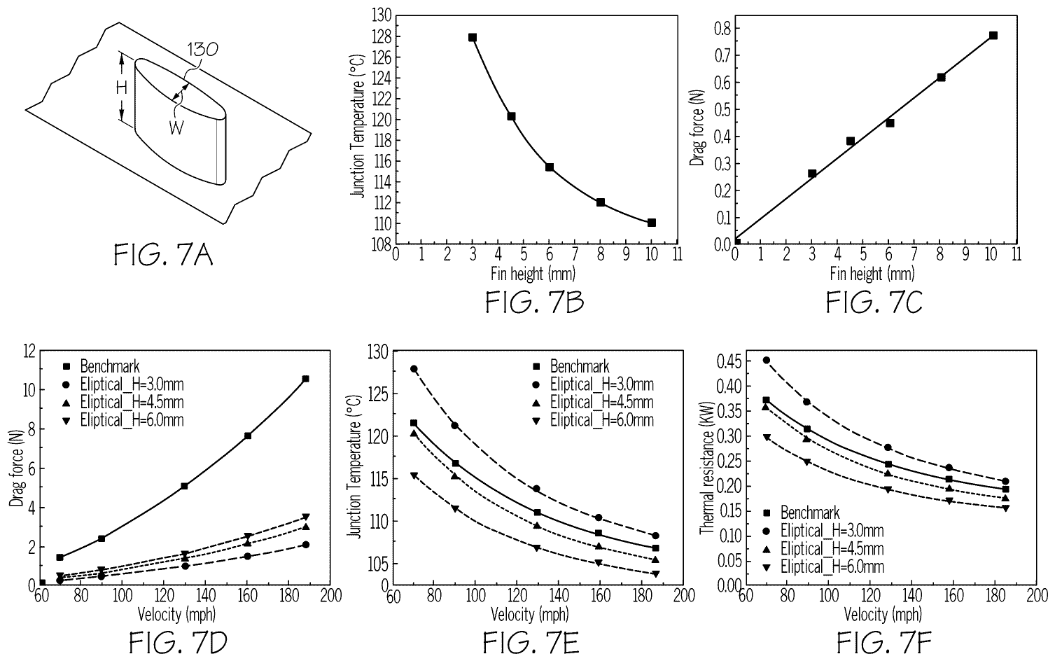

After the optimization procedure, the drag force of heat sink structures at the full speed mode had been reduced from 11 N to around 2 N. To further reduce the drag force under high air speed, in some embodiments an actuatable inclined baffle 192 may be provided, as shown in FIG. 8. The baffle 192 is located on a surface of an airfoil 104 of an aircraft 102 at the upwind side in front of a heat sink 124 on the E-UAV's airfoil. At the low speed, the baffle 192 is down in a stowed position as shown by the dashed lines in FIG. 8 such that it is flush or nearly flush with the airfoil 104. However, at the high speed, the front baffle 192 is lifted so that the baffle 192 is positioned in an inclined state. The baffle 192 may be actuated between states by any appropriate actuator. The vertical height of the baffle 192 in the inclined state should be the same or nearly the same as the height of the fins. However, the vertical height of the baffle 192 may be other suitable heights that may or may not be the same as the height of the fins. The inclined baffle 192 reduces the drag force by leading the air flowing through from the top of heat sink 124 at the high speed.

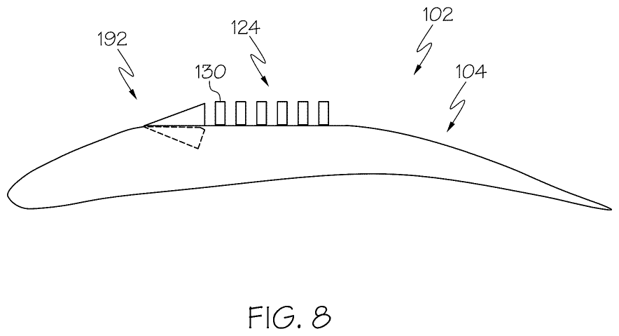

FIG. 9A shows the relation between the inclined angle with the drag force at the full speed mode for the non-uniform distributed elliptical heat sink 180 as shown in FIG. 6B with a fin height at 3 mm. It was found that the overall structural drag force was notably decreased until the inclined angle increased from 0 to 15 degrees. After that, the drag force appeared to rebound.

FIG. 9B shows the relation between the inclined angle with the junction temperature at full speed mode. The junction temperature was consistently increased with the inclined angle of the baffle 192; however, it was always lower than 130 Celsius, the upper limit, and fell into the acceptable region, which ensured the normal operation of power electronic devices 114. Consequently, the optimal inclined angle was chosen as 15 degrees, which further reduced the overall structural drag force from 2.05 N to 1.31 N.

FIG. 9C and FIG. 9D show the performance results of the baffle 192 switching during the flight. When the airflow velocity was lower than 130 mph, the front panel remained down as one part of the airfoil. At 130 mph (209 kph), the baffle 192 was lifted to the inclined state, and there was a sudden decrease on the drag force and a sudden increase on the junction temperature. It is noted embodiments are not limited to 130 mph, and that any velocity may be utilized. This motion targeted to eliminate the overall drag force of the aircraft 102 under high-speed flying but also ensured the normal operation of power electronics below the temperature upper limit, even it would decrease the thermal performance.

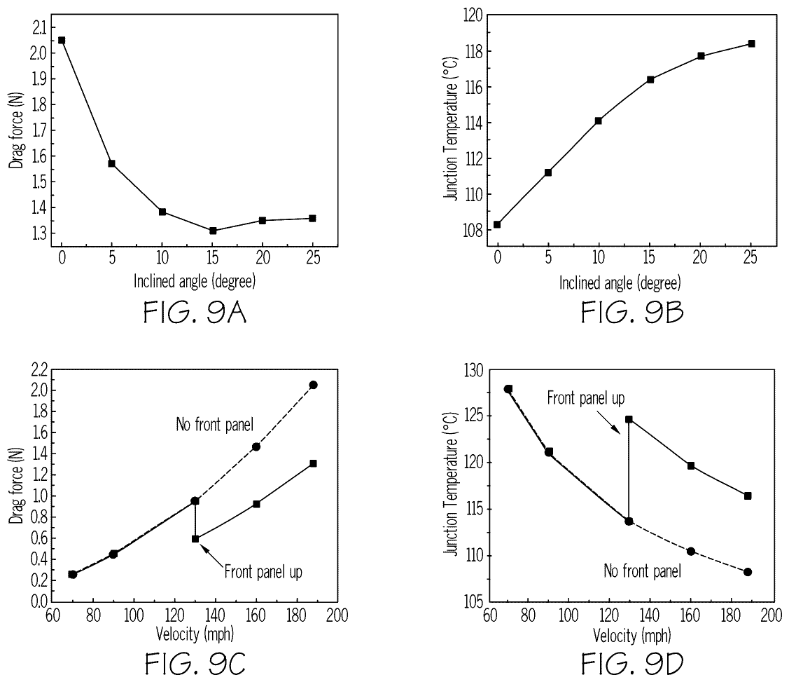

FIG. 10 shows an example airfoil 104 of an aircraft 102 having multiple baffles 192 and electronics assemblies with heat sinks 130. Any number of electronic assemblies 106 may be provided at any location on the aircraft 102. Embodiments are not limited to placing the electronics assembly 106 on the airfoil 104.

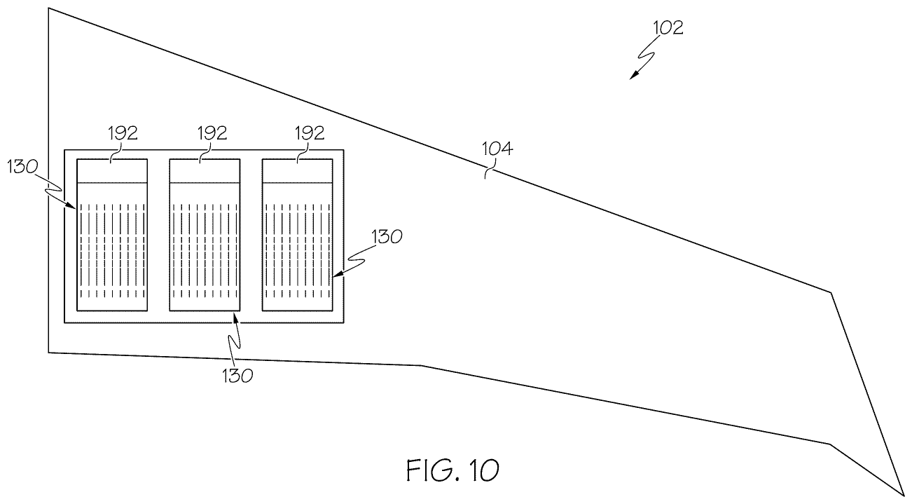

In some embodiments, one or more heat sinks of one or more electronics assemblies 106 placed on an airfoil 104 may be covered by a streamline stack of covers 194. The covers 194 may be placed on one or more tracks 196 placed across the airfoil 104 proximate the one or more electronic electronics assemblies 106. The covers 194 may be stacked in a nested arrangement as shown in FIG. 11A when not in use. Any appropriate actuator may allow the covers 194 of the stack to slide across the track 196 in a direction as indicated by arrow A to fully cover the heat sinks of the one or more electronic electronics assemblies 106 on the airfoil 104.

FIG. 11B shows an example individual cover 194 for fully covering heat sinks. The cover has a shape that matches the contour of the airfoil 104 to minimize drag.

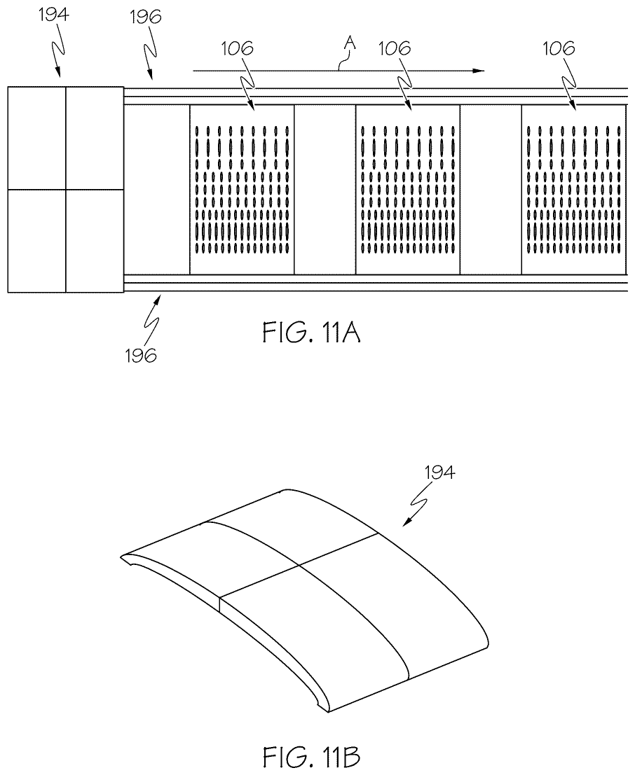

Referring to FIG. 12A, in some embodiments, the stack of covers 198 may only partially cover the heat sink 124 of the electronic electronics assemblies 106, such as covering the front half of the heat sink 124. FIG. 12B shows a close-up view of an individual partial cover 198 that partially covers the heat sink 124 when moved in a direction as indicated by arrow A. This embodiment may provide a balance between cooling and drag. The stack of covers 198 may be deployed by any appropriate actuator.

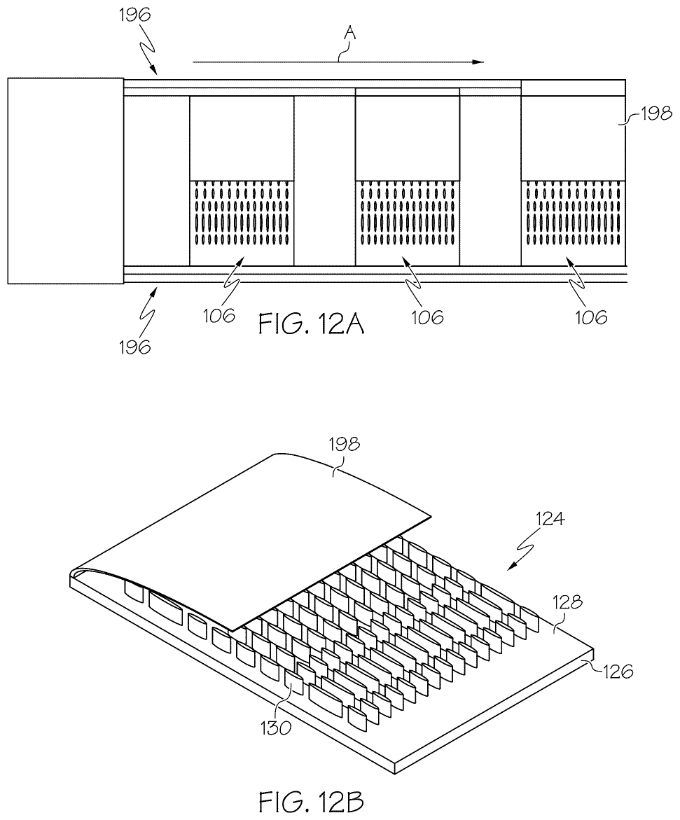

Referring to FIG. 13, in some embodiments, the one or more heat sinks may be placed directly on an inclined plate 202 that acts as a panel on the airfoil 104. The inclined plate 202 may be tilted upwards by any suitable actuator 204 to increase the airflow to the heatsinks to aid cooling, or tilted downwards to decrease the drag force on the airfoil. FIG. 13 illustrates the plate 202 in a retracted state such that it is flush or nearly flush with the rest of the airfoil 104.

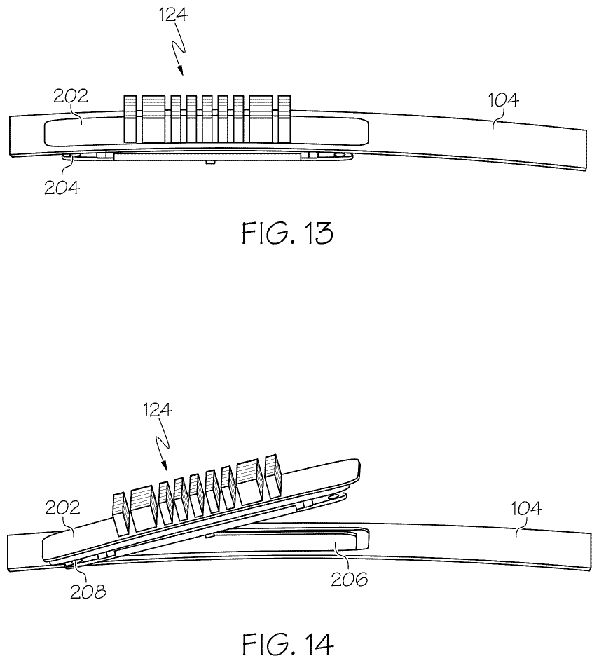

FIG. 14 illustrates the plate 202 in an inclined state after having been tilted by the actuator 204. In the inclined state the plate 202 is removed from a recess 206 within the airfoil 104. The plate 202 may be inclined to any suitable position based on the demands of the aircraft at the time. In any of the above embodiments, the moveable part may be used as a flight control surface, such as an air brake to increase drag and slow down the aircraft. That is, by the inclined front baffle 192, the cover 194 stack, or the inclined plate 202 moving into the airflow across the airfoil 104 the drag of the airfoil may be increased which may slow down the aircraft.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

1. A heat sink assembly comprising a heat sink, the heat sink
comprising: a plate having a surface; and
an array of fins extending from the surface, wherein:
each fin is elliptical in cross section such that each fin has a length that is greater than a width; and
fins of the array of fins are aligned such that an axis defined by the length is in a common direction among the array of fins.

2. The heat sink assembly of claim 1, wherein:
the array of fins comprises a plurality of rows; and
in each row, the width of the fins within the row inwardly decrease.

3. The heat sink assembly of claim 1, wherein:
the array of fins comprises a first group of fins having a first fin density, a second group of fins having a second fin density, and a third group of fins having a third fin density; and
the first fin density, the second fin density and the third fin density are unequal among each other.

4. The heat sink assembly of claim 3, wherein the second fin density is greater than the first fin density and the third fin density is greater than the second fin density.

5. The heat sink assembly of claim 1, wherein the width is within a range of 0.6 mm to 1 mm, including endpoints.

6. The heat sink assembly of claim 1, wherein the plate is configured to be positioned at a retracted position and an inclined position.

7. The heat sink assembly of claim 1, wherein the heat sink assembly further comprises:
a baffle proximate the heat sink; and
an actuator coupled to the baffle, wherein the actuator is operable to transition the baffle between a retracted state and an inclined state such that in the inclined state the baffle airflow is led at a top of the array of fins.

8. The heat sink assembly of claim 1, further comprising a track and at least one cover, wherein the at least one cover is operable to be in a stowed position and a covered position that at least partially covers the array of fins.

9. The heat sink assembly of claim 8, wherein the at least one cover fully covers the array of fins in the covered position.

10. The heat sink assembly of claim 8, wherein:
the heat sink assembly further comprises one or more additional heat sinks;
the at least one cover comprises a plurality of covers that at least partially cover the heat sink and the one or more additional heat sinks when in the covered position; and
the plurality of covers is in a nested configuration when in the stowed position.

11. An assembly comprising:
a power electronics package comprising a plurality of power electronic devices; and
a heat sink thermally coupled to the power electronics package, the heat sink comprising:
a plate having a surface; and
an array of fins extending from the surface, wherein:
each fin is elliptical in cross section such that each fin has a length that is greater than a width; and
fins of the array of fins are aligned such that an axis defined by the length is in a common direction among the array of fins.

12. The assembly of claim 11, wherein:
the array of fins comprises a plurality of rows; and
in each row, the width of the fins within the row inwardly decrease.

13. The assembly of claim 11, wherein:
the array of fins comprises a first group of fins having a first fin density, a second group of fins having a second fin density, and a third group of fins having a third fin density; and
the first fin density, the second fin density and the third fin density are unequal among each other.

14. The assembly of claim 13, wherein the second fin density is greater than the first fin density and the third fin density is greater than the second fin density.

15. The assembly of claim 11, wherein the plate is configured to be positioned at a retracted position and an inclined position.

16. The assembly of claim 11, wherein the assembly further comprises:
a baffle proximate the heat sink; and
an actuator coupled to the baffle, wherein the actuator is operable to transition the baffle between a retracted state and an inclined state such that in the inclined state the baffle airflow is led at a top of the array of fins.

17. The assembly of claim 11, further comprising a track and at least one cover, wherein the at least one cover is operable to be in a stowed position and a covered position that at least partially covers the array of fins.

18. The assembly of claim 17, wherein the at least one cover fully covers the array of fins in the covered position.

19. The assembly of claim 17, wherein:
the assembly further comprises one or more additional heat sinks;
the at least one cover comprises a plurality of covers that at least partially cover the heat sink and the one or more additional heat sinks when in the covered position; and
the plurality of covers is in a nested configuration when in the stowed position.

20. An aircraft comprising:
an airfoil comprising a recess;
a power electronics package comprising a plurality of power electronic devices; and
a heat sink thermally coupled to the power electronics package, the heat sink comprising:
a plate having a surface; and
an array of fins extending from the surface, wherein:
each fin is elliptical in cross section such that each fin has a length that is greater than a width; and
fins of the array of fins are aligned such that an axis defined by the length is in a common direction among the array of fins; and
an actuator coupled to the plate and operable to move the plate between a retracted position and an inclined position, wherein when the plate is in the retracted position the plate is within the recess of the airfoil.
